(19) United States
(12) Patent Application Publication
(10) Pub. No.: US 2025/0280479 A1
(43) Pub. Date: Sep. 4, 2025

(54) DRIVE CIRCUIT FOR A LIGHT-EMITTING DIODE LIGHT SOURCE

(71) Applicant: Lutron Technology Company LLC, Coopersburg, PA (US)

(72) Inventors: Stuart W. DeJonge, Riegelsville, PA (US); Robert C. Newman, JR., Emmaus, PA (US)

(73) Assignee: Lutron Technology Company LLC, Coopersburg, PA (US)

(21) Appl. No.: 19/212,129

(22) Filed: May 19, 2025

Related U.S. Application Data
(63) Continuation of application No. 18/431,090, filed on Feb. 2, 2024, now Pat. No. 12,309,892.
Application No. 18/431,090 is a continuation of application No. 17/750,647, filed on May 23, 2022, now Pat. No. 11,930,574.
Application No. 17/750,647 is a continuation of application No. 17/134,945, filed on Dec. 28, 2020, now Pat. No. 11,343,894.
Application No. 17/134,945 is a continuation of application No. 16/557,179, filed on Aug. 30, 2019, now Pat. No. 10,904,976.
(60) Provisional application No. 62/725,467, filed on Aug. 31, 2018.

(51) Int. Cl. H05B 45/40; H03K 7/08; H05B 45/20; H05B 47/19

(52) U.S. Cl. CPC H05B 45/40; H03K 7/08; H05B 47/19; H05B 45/20

(57) ABSTRACT

A controllable lighting device may utilize a controllable impedance circuit to conduct a load current through an LED light source. The controllable impedance circuit may be coupled in series with a first switching device, which may be rendered conductive and non-conductive via a pulse-width modulated signal to adjust an average magnitude of the load current. The controllable lighting device may further comprise a control loop circuit that includes a second switching device. The second switching device may be rendered conductive and non-conductive in coordination with the first switching device to control when a feedback signal is provided to the control loop circuit and used to control the LED light source. The control loop circuit may be characterized by a time constant that is significantly greater than an operating period of the load current.

### CROSS-REFERENCE TO RELATED APPLICATIONS

This application is a continuation of U.S. application Ser. No. 18/431,090 filed Feb. 2, 2024; which is a continuation of U.S. application Ser. No. 17/750,647 filed May 23, 2022, now U.S. Pat. No. 11,930,574 issued Mar. 12, 2024; which is a continuation of U.S. application Ser. No. 17/134,945 filed Dec. 28, 2020, now U.S. Pat. No. 11,343,894, issued May 24, 2022; which is continuation of U.S. application Ser. No. 16/557,179, filed Aug. 30, 2019, now U.S. Pat. No. 10,904,976, issued Jan. 26, 2021; which claims the benefit of Provisional U.S. Patent Application No. 62/725,467, filed Aug. 31, 2018, the disclosures of which are incorporated herein by reference in their entireties.

### BACKGROUND

Light-emitting diode (LED) light sources (e.g., LED light engines) are replacing conventional incandescent, fluorescent, and halogen lamps as a primary form of lighting devices. LED light sources may comprise a plurality of light-emitting diodes mounted on a single structure and provided in a suitable housing. LED light sources may be more efficient and provide longer operational lives as compared to incandescent, fluorescent, and halogen lamps. An LED driver control device (e.g., an LED driver) may be coupled between a power source, such as an alternating-current (AC) power source or a direct-current (DC) power source, and an LED light source for regulating the power supplied to the LED light source. For example, the LED driver may regulate the voltage provided to the LED light source, the current supplied to the LED light source, or both the current and voltage.

Different control techniques may be employed to drive LED light sources including, for example, a current load control technique and a voltage load control technique. An LED light source driven by the current load control technique may be characterized by a rated current (e.g., approximately 350 milliamps) to which the magnitude (e.g., peak or average magnitude) of the current through the LED light source may be regulated to ensure that the LED light source is illuminated to the appropriate intensity and/or color. An LED light source driven by the voltage load control technique may be characterized by a rated voltage (e.g., approximately 15 volts) to which the voltage across the LED light source may be regulated to ensure proper operation of the LED light source. If an LED light source rated for the voltage load control technique includes multiple parallel strings of LEDs, a current balance regulation element may be used to ensure that the parallel strings have the same impedance so that the same current is drawn in each of the parallel strings.

The light output of an LED light source may be dimmed. Methods for dimming an LED light source may include, for example, a pulse-width modulation (PWM) technique and a constant current reduction (CCR) technique. In pulse-width modulation dimming, a pulsed signal with a varying duty cycle may be supplied to the LED light source. For example, if the LED light source is being controlled using a current load control technique, the peak current supplied to the LED light source may be kept constant during an on-time of the duty cycle of the pulsed signal. The duty cycle of the pulsed signal may be varied, however, to vary the average current supplied to the LED light source, thereby changing the intensity of the light output of the LED light source. As another example, if the LED light source is being controlled using a voltage load control technique, the voltage supplied to the LED light source may be kept constant during the on-time of the duty cycle of the pulsed signal. The duty cycle of the load voltage may be varied, however, to adjust the intensity of the light output. Constant current reduction dimming may be used if an LED light source is being controlled using the current load control technique. In constant current reduction dimming, current may be continuously provided to the LED light source. The DC magnitude of the current provided to the LED light source, however, may be varied to adjust the intensity of the light output.

Examples of LED drivers are described in U.S. Pat. No. 8,492,987, issued Jul. 23, 2013, entitled LOAD CONTROL DEVICE FOR A LIGHT-EMITTING DIODE LIGHT SOURCE; U.S. Pat. No. 9,655,177, issued May 16, 2017, entitled FORWARD CONVERTER HAVING A PRIMARY-SIDE CURRENT SENSE CIRCUIT; and U.S. Pat. No. 9,247,608, issued Jan. 26, 2016, entitled LOAD CONTROL DEVICE FOR A LIGHT-EMITTING DIODE LIGHT SOURCE; the entire disclosures of which are hereby incorporated by reference.

### SUMMARY

Methods and apparatus are described herein for controlling an LED light source. A controllable impedance circuit may be coupled in series with the LED light source and configured to conduct a load current through the LED light source. A first switching device may be connected in series with the controllable impedance circuit while a feedback circuit is configured to generate a feedback signal indicative of a magnitude of the load current conducted through the LED light source. The feedback circuit may be coupled to a control loop circuit configured to generate a drive signal for controlling the controllable impedance circuit based on the feedback signal. The control loop circuit may comprise a second switching device and/or a filter circuit. The second switching device may be capable of being rendered conductive and non-conductive to control when the feedback signal is used to generate the drive signal (e.g., after the feedback signal is passed through the filter circuit).

A digital control circuit may control the control loop circuit to adjust a peak magnitude of the load current conducted through the LED light source toward a target magnitude. The digital control circuit may render the first switching device conductive and non-conductive via a pulse-width modulated (PWM) signal and adjust a duty cycle of the PWM signal to adjust an average magnitude of the load current. The digital control circuit may further render the second switching device conductive and non-conductive in coordination with the PWM signal. For example, the digital control circuit may be configured to render the second switching device conductive at the end of a first time period after the digital control circuit renders the first switching device conductive, and the digital control circuit may be further configured to render the second switching device non-conductive at the beginning of a second time period before the digital control circuit renders the first switching device non-conductive.

The control loop circuit described herein may comprise an integrator circuit. The control loop circuit may receive a target current control signal from the digital control circuit and generate the drive signal by integrating the difference between the target current control signal and the feedback signal via the integrator circuit. The control loop circuit may be characterized by a time constant that is greater than a load current period of the load current conducted by the controllable impedance circuit.

One or more of the components and/or functions described herein may be implemented digitally. For example, sampling of the feedback signal may be controlled by a digital control circuit and filtering operations may be conducted using a digital low-pass filter.

### BRIEF DESCRIPTION OF THE DRAWINGS

FIG. 1 is a simplified block diagram of a controllable electrical device, such as a controllable light source.

FIG. 2 is a simplified schematic diagram of a drive circuit, such as a light-emitting diode (LED) drive circuit, and a control loop circuit of an electrical device, such as the controllable light source of FIG. 1.

FIG. 3 are example plots of the relationships between various operating parameters of the controllable light source of FIG. 1 and a target intensity of the controllable light source.

FIGS. 4A-4C are diagrams of simplified waveforms illustrating the operation of the drive circuit and the control loop circuit of FIG. 2.

FIG. 5 is a simplified flow diagram of an example control procedure for controlling the control loop circuit of FIG. 2.

FIG. 6 is a simplified schematic diagram of a circuit that may be used to realize the functionality of the drive circuit and the control loop circuit shown in FIG. 2.

FIG. 7 is a simplified flow diagram of an example control procedure for controlling the circuit shown in FIG. 6.

### DETAILED DESCRIPTION

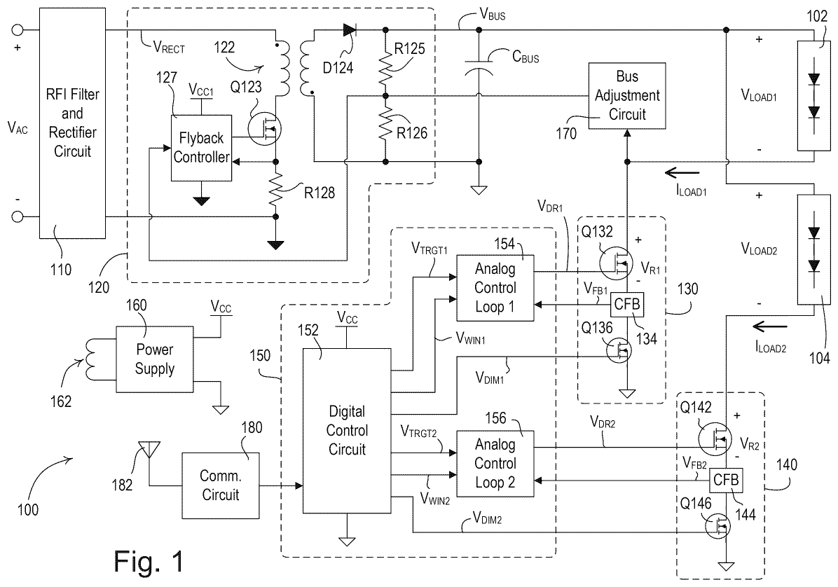

FIG. 1 is a simplified block diagram of a controllable electrical device, such as a controllable lighting device 100 (e.g., a controllable light source). For example, the controllable lighting device 100 may be a lamp that comprise one or more light sources, such as light-emitting diode (LED) light sources 102, 104 (e.g., LED light engines). The LED light sources 102, 104 may be controlled to adjust an intensity and/or a color (e.g., a color temperature) of a cumulative light output of the controllable lighting device 100. Each LED light source 102, 104 is shown in FIG. 1 as a plurality of LEDs connected in series but may comprise a single LED or a plurality of LEDs connected in parallel or a suitable combination thereof, depending on the particular lighting system. In addition, each LED light source 102, 104 may comprise one or more organic light-emitting diodes (OLEDs). The controllable lighting device 100 may include a plurality of different LED light sources, which may be rated at different magnitudes of load current and voltage. While not shown in FIG. 1, the controllable lighting device 100 may comprise a housing (e.g., a translucent housing) in which the LED light sources are located and through which the LED light sources may shine. For example, the controllable lighting device 100 may be capable of providing warm-dimming such that the color temperature of the cumulative light output shifts towards a warm-white color temperature as the intensity of the cumulative light output is decreased. For example, the first LED light source 102 may comprise a white LED light source and the second LED light source 104 may comprise a warm-white (e.g., red) LED light source, and the first LED light source 102 may have a higher power rating than the second LED light source 104.

The controllable lighting device 100 may be a screw-in LED lamp configured to be screwed into a standard Edison socket. The controllable light device 100 may comprise a screw-in base that includes a hot connection H and a neutral connection N for receiving an alternating-current (AC) voltage V_{AC} from an AC power source (not shown). The hot connection H and the neutral connection N may also be configured to receive a direct-current (DC) voltage from a DC power source. The controllable lighting device 100 may comprise a radio-frequency interference (RFI) filter and rectifier circuit 110, which may receive the AC voltage V_{AC}. The RFI filter and rectifier circuit 110 may operate to minimize the noise provided on the AC power source and to generate a rectified voltage V_{RECT}.

The controllable lighting device 100 may comprise a power converter circuit 120, such as a flyback converter, which may receive the rectified voltage V_{RECT} and generate a variable direct-current (DC) bus voltage V_{BUS} across a bus capacitor C_{BUS}. The power converter circuit 120 may comprise other types of power converter circuits, such as, for example, a boost converter, a buck converter, a buck-boost converter, a single-ended primary-inductance converter (SEPIC), a Ćuk converter, or any other suitable power converter circuit for generating an appropriate bus voltage. The power converter circuit 120 may provide electrical isolation between the AC power source and the LED light source 102, 104 and may operate as a power factor correction (PFC) circuit to adjust the power factor of the controllable lighting device 100 towards a power factor of one.

As shown in FIG. 1, the flyback converter 120 may comprise a flyback transformer 122, a field-effect transistor (FET) Q123, a diode D124, a resistor R125, a resistor R126, a flyback control circuit 127, and/or a feedback resistor R128. The flyback transformer 122 may comprise a primary winding and a secondary winding. The primary winding may be coupled in series with the FET Q123. Although illustrated as the FET Q123, any switching transistor or other suitable semiconductor switch may be coupled in series with the primary winding of the flyback transformer 122. The secondary winding of the flyback transformer 122 may be coupled to the bus capacitor C_{BUS} via the diode D124. A bus voltage feedback signal V_{BUS-FB} may be generated, e.g., by a voltage divider comprising the resistors R125, R126 coupled across the bus capacitor C_{BUS}. The flyback control circuit 127 may receive the bus voltage feedback signal V_{BUS-FB} and a control signal representative of the current through the FET Q123 from the feedback resistor R128, which may be coupled in series with the FET Q123. The flyback control circuit 127 may control the FET Q123 to selectively conduct current through the flyback transformer 122 to generate the bus voltage V_{BUS}. The flyback control circuit 127 may render the FET Q123 conductive and non-conductive, for example, to control the magnitude of the bus voltage V_{BUS} towards a target bus voltage V_{BUS-TRGT} in response to the DC magnitude of the bus voltage feedback signal V_{BUS-FB} and the magnitude of the current through the FET Q123.

The controllable lighting device 100 may comprise one or more load regulation circuits, such as LED drive circuits 130, 140, for controlling power delivered to (e.g., the intensities of) the LED light sources 102, 104, respectively. The LED drive circuits 130, 140 may each receive the bus voltage V_{BUS} and may adjust magnitudes of respective load currents I_{LOAD1}, I_{LOAD2} conducted through the LED light sources 102, 104 and/or magnitudes of respective load voltages V_{LOAD1}, V_{LOAD2} generated across the LED light sources. One or more of the LED drive circuits 130, 140 may comprise a controllable-impedance circuit, such as a linear regulator, for example, as described herein. One or more of the LED drive circuits 130, 140 may comprise a switching regulator, such as a buck converter for example. Examples of various embodiments of LED drive circuits are described in U.S. Pat. No. 8,492,987, filed Jul. 23, 2013, and U.S. Pat. No. 9,253,829, issued Feb. 2, 2016, both entitled LOAD CONTROL DEVICE FOR A LIGHT-EMITTING DIODE LIGHT SOURCE, the entire disclosures of which are hereby incorporated by reference.

The controllable lighting device 100 may comprise a control circuit 150 for controlling the LED drive circuits 130, 140 to control the magnitudes of the respective load currents I_{LOAD1}, I_{LOAD2} conducted through the LED light sources 102, 104 to adjust the respective intensities of the LED light sources. The control circuit 150 may be configured to turn both of the LED light sources 102, 104 on and off to turn the controllable lighting device 100 on and off, respectively. The control circuit 150 may be configured to control the respective intensities of the LED light sources 102, 104 to control the intensity and/or the color (e.g., the color temperature) of the cumulative light emitted by the controllable lighting device 100. The control circuit 150 may be configured to adjust (e.g., dim) a present intensity L_{PRES} of the cumulative light emitted by the controllable lighting device 100 towards a target intensity L_{TRGT}, which may range across a dimming range of the controllable light source, e.g., between a low-end intensity L_{LE} (e.g., a minimum intensity, such as approximately 0.1%-1.0%) and a high-end intensity L_{HE} (e.g., a maximum intensity, such as approximately 100%). The control circuit 150 may be configured to adjust a present color temperature T_{PRES} of the cumulative light emitted by the controllable lighting device 100 towards a target color temperature T_{TRGT}, which may range between a cool-white color temperature (e.g., approximately 3100-4500 K) and a warm-white color temperature (e.g., approximately 2000-3000 K).

The control circuit 150 may comprise a digital control circuit 152, such as, for example, a microprocessor, a microcontroller, a programmable logic device (PLD), an application specific integrated circuit (ASIC), a field-programmable gate array (FPGA), or any other suitable processing device or controller. The control circuit 150 may comprise a memory (not shown) configured to store operational characteristics of the controllable lighting device 100 (e.g., the target intensity L_{TRGT}, the target color temperature T_{TRGT}, the low-end intensity L_{LE}, the high-end intensity L_{HE}, etc.). The memory may be implemented as an external integrated circuit (IC) or as an internal circuit of the digital control circuit 152. The controllable lighting device 100 may comprise a power supply 160 that may be coupled to a winding 162 of the flyback transformer 122 of the power converter circuit 120 and may be configured to generate a supply voltage V_{CC} for powering the digital control circuit 152 and other low-voltage circuitry of the controllable lighting device.

The control circuit 150 may also comprise control loop circuits (e.g., analog control loop circuits) 154, 156 for controlling the LED drive circuits 130, 140, respectively. The LED drive circuits 130, 140 may comprise respective regulation devices (e.g., regulation field-effect transistors (FET) Q132, Q142) coupled (e.g., in series) with the LED light sources 102, 104, respectively, for conducting the load currents I_{LOAD1}, I_{LOAD2}. Each regulation FET Q132, Q142 may comprise any type of suitable power semiconductor switch, such as, for example, a bipolar junction transistor (BJT), and/or an insulated-gate bipolar transistor (IGBT). The control loop circuits 154, 156 may generate respective drive signals V_{DR1}, V_{DR2} that may be received by gates of the regulation FETs Q132, Q142 for controlling the regulation FETs in the linear region to provide controllable impedances in series with the LED light sources 102, 104, respectively (e.g., to operate the regulation FETs Q132, Q142 as linear regulators). When the regulation FETs Q132, Q142 are conducting the respective load currents I_{LOAD1}, I_{LOAD2}, respective regulator voltages V_{R1}, V_{R2} may be developed across the regulation FETs Q132, Q142.

The regulation FETs Q132, Q142 may be coupled (e.g., in series) with respective feedback circuits (e.g., current feedback (CFB) circuits) 134, 144. The current feedback circuits 134, 144 may be coupled to the control loop circuits 154, 156 of the control circuit 150 and may generate respective current feedback signals V_{FB1}, V_{FB2}, which may be received by the control loop circuits 154, 156. The control loop circuits 154, 156 may be configured to adjust the magnitudes (e.g., DC magnitudes) of the drive signals V_{DR1}, V_{DR2} provided to the gates of the regulation FETs Q132, Q142 in response to the magnitudes of the current feedback signals V_{FB1}, V_{FB2}, respectively. The digital control circuit 152 may generate respective target-current control signals V_{TRGT1}, V_{TRGT2}, which may also be received by the control loop circuits 154, 156. The control loop circuits 154, 156 may be configured to adjust the magnitudes of the drive signals V_{DR1}, V_{DR2} provided to the gates of the regulation FETs Q132, Q142 to control the magnitudes of the load current I_{LOAD1}, I_{LOAD2} towards respective target current I_{TRGT1}, I_{TRGT2} that are set by the target-current control signals V_{TRGT1}, V_{TRGT2}.

The LED drive circuits 130, 140 may further comprise dimming devices (e.g., dimming FETs Q136, Q146 or another type of semiconductor switches) coupled (e.g., in series) with the regulation FETs Q132, Q142 and the current feedback circuits 134, 144, respectively. The digital control circuit 152 may generate respective dimming control signals V_{DIM1}, V_{DIM2} that may be received by gates of the respective dimming FETs Q136, Q146 for rendering the dimming FETs conductive and non-conductive to adjust average magnitudes of the load currents I_{LOAD1}, I_{LOAD2}, respectively. For example, the digital control circuit 152 may be configured to pulse-width modulate (PWM) the load currents I_{LOAD1}, I_{LOAD2} by generating the dimming control signals V_{DIM1}, V_{DIM2} as pulse-width modulated (PWM) signals at a dimming frequency f_{DIM}. The digital control circuit 152 may be configured to adjust respective duty cycles DC₁, DC₂ of the dimming control signals V_{DIM1}, V_{DIM2} to adjust the average magnitudes of the load currents I_{LOAD1}, I_{LOAD2}, respectively. When the digital control circuit 152 is pulse-width modulating the dimming control signals V_{DIM1}, V_{DIM2}, the load currents I_{LOAD1}, I_{LOAD2} may be characterized by a load-current frequency f_{LOAD} (e.g., which is approximately equal to the dimming frequency f_{DIM} of the dimming control signals V_{DIM1}, V_{DIM2}) and a corresponding load-current period T_{LOAD}. The load-current frequency f_{LOAD} may be high enough to prevent flickering that may be visible to the human eye.

The dimming FETs Q136, Q146 may be coupled between the respective current feedback circuits 134, 144 and circuit common. The digital control circuit 152 may be configured to control when the control loop circuits 154, 156 are responsive to the respective current feedback signals V_{FB1}, V_{FB2} for adjusting the magnitudes of the drive signals V_{DR1}, V_{DR2}. The digital control circuit 152 may be configured to render the control circuit circuits 154, 156 responsive and non-responsive to the respective current feedback signals V_{FB1}, V_{FB2} in coordination with the respective dimming control signals V_{DIM1}, V_{DIM2}. For example, the digital control circuit 152 may be configured to enable the control loop circuits 154, 156 to be responsive to the respective current feedback signals V_{FB1}, V_{FB2} during feedback windows TWIN that may be approximately the same length as or slightly shorter than the time periods when the dimming FETs Q136, Q146 are rendered conductive. The digital control circuit 152 may be configured to render the control loop circuits 154, 156 responsive to the respective current feedback signals V_{FB1}, V_{FB2} at approximately the same time or slightly after the dimming FETs Q136, Q146 are rendered conductive. The digital control circuit 152 may be configured to render the control loop circuits 154, 156 non-responsive to the respective current feedback signals V_{FB1}, V_{FB2} at approximately the same time or slightly before the dimming FETs Q136, Q146 are rendered non-conductive. To control the operation of the respective control loop circuits 154, 156, the digital control circuit 152 may generate respective feedback window control signals V_{WIN1}, V_{WIN2} that may be received by the control loop circuits for enabling and disabling when the control loop circuits are responsive to the respective current feedback signals V_{FB1}, V_{FB2}. As a result, each control loop circuit 154, 156 may be responsive to a peak magnitude I_{PK} of the respective current feedback signal V_{FB1}, V_{FB2} (e.g., when the dimming FETs Q136, Q146 are conductive).

The techniques described herein may help prevent erroneous operation of the controllable lighting device 100 in various situations. For example, since the dimming FETs Q136, Q146 may be coupled between the respective current feedback circuits 134, 144 and the circuit common, the magnitudes of the current feedback signals V_{FB1}, V_{FB2} may be pulled up towards the bus voltage V_{BUS} when the dimming FETs Q136, Q146 are non-conductive, which may cause the control loop circuits 154, 156 to incorrectly drive the regulation FETs Q132, Q142. By configuring the digital control circuit 152 to control (e.g., at least with respect to timing) when the control loop circuits 154, 156 are responsive to the respective current feedback signals V_{FB1}, V_{FB2} for adjusting the magnitudes of the drive signals V_{DR1}, V_{DR2}, erroneous generation of the drive signals V_{DR1}, V_{DR2} may be avoided.

The controllable lighting device 100 may comprise a bus adjustment circuit 170 for controlling the magnitude of the bus voltage V_{BUS} (e.g., to make sure that the regulation FETs Q132, Q142 do not dissipate too much power). For example, the bus adjustment circuit 170 may be coupled to the junction of the first regulation FET Q132 and the first LED light source 102, and may be responsive to the first regulator voltages V_{R1} across the first regulation FET Q132. The bus adjustment circuit 170 may be coupled to the junction of the resistors R125, R126 for adjusting the magnitude of the bus voltage feedback signal V_{BUS-FB} to cause the flyback control circuit 127 to adjust the magnitude of the bus voltage V_{BUS}. For example, the bus adjustment circuit 170 may adjust the magnitude of the bus voltage V_{BUS} to control the magnitude of the first regulator voltage V_{R1} to be less than a maximum regulator voltage threshold VR-MAX (e.g., approximately 0.6 volts), for example, to prevent the power dissipated in regulation FETs Q132, Q142 from becoming too large. In examples (e.g., as shown in FIG. 1), the bus adjustment circuit 170 may be only coupled to the first regulation transistor Q132. Since the first LED light source 102 may have a higher power rating than the second LED light source 104 (as previously mentioned), adjustments of the magnitude of the bus voltage V_{BUS} in response to the magnitude of the first regulator voltage V_{R1} to make sure that the first regulation FET Q132 does not dissipate too much power may also ensure that the second regulation FET Q142 does not dissipate too much power.

The controllable lighting device 100 may comprise a communication circuit 180 coupled to the digital control circuit 152. The communication circuit 180 may comprise a wireless communication circuit, such as, for example, a radio-frequency (RF) transceiver coupled to an antenna 182 for transmitting and/or receiving RF signals. The wireless communication circuit may be an RF transmitter for transmitting RF signals, an RF receiver for receiving RF signals, or an infrared (IR) transmitter and/or receiver for transmitting and/or receiving IR signals. The communication circuit 180 may be coupled to the hot connection H and the neutral connection N of the controllable lighting device 100 for transmitting a control signal via the electrical wiring using, for example, a power-line carrier (PLC) communication technique. The digital control circuit 152 may be configured to determine the target intensity L_{TRGT} for the controllable lighting device 100 in response to messages (e.g., digital messages) received via the communication circuit 180. The digital control circuit 152 may be configured to determine respective target intensities L_{TRGT1}, L_{TRGT2} for the LED light sources 102, 104 in response to the determined target intensity L_{TRGT} for the controllable lighting device 100.

When the target intensity L_{TRGT1}, L_{TRGT2} of at least one of the LED light sources 102, 104 is greater than or equal to a transition intensity L_{TRAN}, the digital control circuit 152 may be configured to render the respective dimming FET Q136, Q146 conductive (e.g., conductive at all times) and adjust the intensity of the respective LED light source using a constant current reduction (CCR) dimming technique. Using the CCR dimming technique, the digital control circuit 152 may adjust the respective target-current control signal V_{TRGT1}, V_{TRGT2} to cause the respective control loop circuit 154, 156 to adjust the average magnitude of the load current I_{LOAD1}, I_{LOAD2} towards the respective target current I_{TRGT1}, I_{TRGT2}. The target currents I_{TRGT1}, I_{TRGT2} may each range between a maximum current IMAX (e.g., at the high-end intensity L_{HE}) and a minimum current IMIN (e.g., at the transition intensity L_{TRAN}).

When the target intensity L_{TRGT1}, L_{TRGT2} of at least one of the LED light sources 102, 104 is less than the transition intensity L_{TRAN}, the digital control circuit 152 may be configured to control the respective dimming FET Q136, Q146 to adjust the intensity of the respective LED light source using a pulse-width modulation (PWM) dimming technique. For example, the digital control circuit 152 may be configured to control the respective target-current control signal V_{TRGT1}, V_{TRGT2} to maintain the respective target current I_{TRGT1}, I_{TRGT2} constant. Using the PWM dimming technique, the digital control circuit 152 may adjust the duty cycle DC₁, DC₂ of the respective dimming control signal V_{DIM1}, V_{DIM2} to adjust the average magnitude of the load current I_{LOAD1}, I_{LOAD2} below the minimum current IMIN. For example, the digital control circuit 152 may adjust the duty cycle DC₁, DC₂ of each of the dimming control signals V_{DIM1}, V_{DIM2} as a function of the respective target intensity L_{TRGT1}, L_{TRGT2}. For example, the digital control circuit 152 may linearly decrease the duty cycle DC₁, DC₂ as the respective target intensity L_{TRGT1}, L_{TRGT2} decreases, and vice versa. Each control loop circuit 154, 156 may continue to regulate the peak magnitudes I_{PK} of the load current I_{LOAD1}, I_{LOAD2} towards the target current I_{TRGT1}, I_{TRGT2} when the respective dimming FET Q136, Q146 is conductive. Each control loop circuit 154, 156 may be characterized by a time constant that is much greater than the load-current period T_{LOAD} of the respective load current I_{LOAD1}, I_{LOAD2}, for example, to help avoid changes in the magnitudes of the respective drive signals V_{DR1}, V_{DR2} when the dimming FETs Q136, Q146 are non-conductive. The time constant may be associated with one or more integrator circuit and/or RC filter circuits comprised in the control loop circuit 154, 156, for example. The value of the time constant may be determined by the electrical properties (e.g., capacitance and/or resistance) of one or more components comprised in the control loop circuit 154, 156.

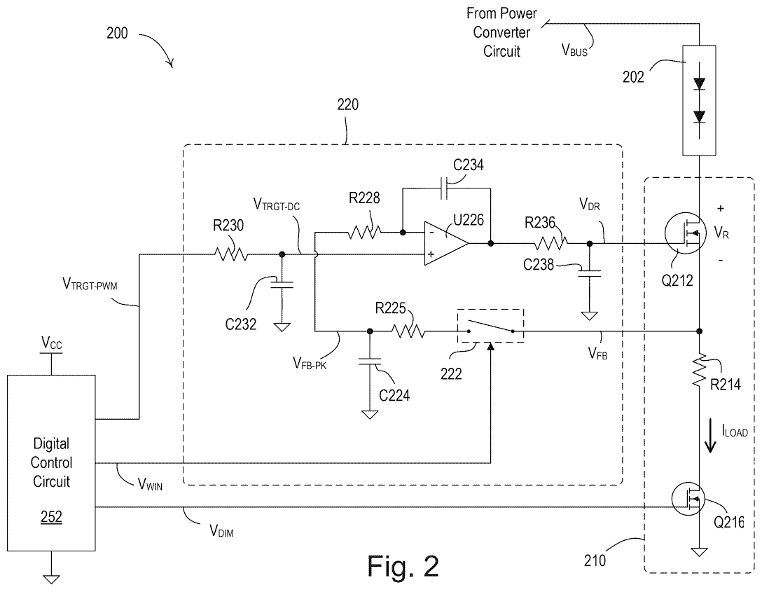

FIG. 2 is a simplified schematic diagram of an LED drive circuit 210 (e.g., one of the LED drive circuits 130, 140) and a control loop circuit 220 (e.g., one of the control loop circuits 154, 156) of an electrical device 200, such as an LED driver or a controllable light source (e.g., the controllable lighting device 100). The LED drive circuit 210 may be coupled in series with an LED light source 202 (e.g., one of the LED light sources 102, 104) for conducting a load current I_{LOAD} through the LED light source. The control loop circuit 220 may generate a drive signal V_{DR} for controlling the LED drive circuit 210 to adjust a magnitude of the load current I_{LOAD} through the LED light source. The LED driver 100 may also comprise a digital control circuit 252 (e.g., the digital control circuit 152) for generating a PWM control signal (e.g., a target-current control signal V_{TRGT-PWM}) that may be received by the control loop circuit 220 for setting a target current I_{TRGT} for the load current I_{LOAD}. The digital control circuit 252 may be configured to adjust the intensity of the LED light source 202 towards a target intensity L_{TRGT} that may range between a minimum intensity L_{MIN} (e.g., approximately 0.1%-1.0%) and a maximum intensity L_{MAX} (e.g., approximately 100%). The minimum intensity L_{MIN} may be approximately the lowest intensity at which the digital control circuit 252 may control the LED light source 202 under steady state conditions (e.g., when the target intensity L_{TRGT} is being held constant).

The LED drive circuit 210 may comprise a regulation device such as a regulation FET Q212 coupled in series with the LED light source 202. The regulation FET Q212 may comprise any type of suitable power semiconductor switch, such as, for example, a bipolar junction transistor (BJT), and/or an insulated-gate bipolar transistor (IGBT). When the regulation FET Q212 is conductive, a regulator voltage VR may be developed across the regulation FET. The LED drive circuit 210 may comprise a current feedback circuit (e.g., a current feedback resistor R214) coupled in series with the regulation FET Q212 for generating a current feedback signal V_{FB} that may have a DC magnitude representative of the magnitude of the load current I_{LOAD}. The LED drive circuit 210 may comprise a dimming device (e.g., such as a dimming FET Q216 or another type of semiconductor switch) coupled between the current feedback resistor R214 and circuit common. The digital control circuit 252 may generate a dimming control signal V_{DIM} that may be received by a gate of the dimming FET Q216. The dimming FET Q216 may be rendered conductive and non-conductive in response to the dimming control signal V_{DIM} for adjusting an average magnitude of the load current I_{LOAD}.

The control loop circuit 220 may receive the current feedback signal V_{FB} generated by the current feedback resistor R214 and/or the PWM target-current control signal V_{TRGT-PWM} generated by the digital control circuit 252. The current feedback signal V_{FB} may be received by a controllable switch 222 comprised in the control loop circuit 220. The controllable switch 222 may be rendered conductive and non-conductive in response to a feedback window control signal V_{WIN} (e.g., a switch control signal) generated by the digital control circuit 252. The controllable switch 222 may be coupled to a filter circuit, which may comprise a capacitor C224 and a resistor R225. When the controllable switch 222 is conductive, the capacitor C224 (e.g., having a capacitance of approximately 1.0 μF) may charge to approximately a peak magnitude I_{PK} of the current feedback signal V_{FB} through the resistor R225 (e.g., having a resistance of approximately 100) for generating a peak-current feedback signal V_{FB-PK} across the capacitor.

The control loop circuit 220 may comprise an operational amplifier U226 comprising an inverting input coupled to receive the current feedback signal V_{FB} through a resistor R228. The control loop circuit 220 may comprise a filter circuit (e.g., a low-pass RC filter circuit) including a resistor R230 (e.g., having a resistance of approximately 1 kΩ) and a capacitor C232 (e.g., having a capacitance of approximately 0.1 μF). The PWM target-current control signal V_{TRGT-PWM} may be received by the resistor R230, such that a DC target-current control signal V_{TRGT-DC} is generated at the junction of the resistor R230 and the capacitor C232 and has a DC magnitude representative of the target current I_{TRGT} for the load current I_{LOAD}. The DC target-current control signal V_{TRGT-DC} may be coupled to a non-inverting input of the operational amplifier U226. For example, the digital control circuit 252 may generate the PWM target-current control signal V_{TRGT-PWM} as a pulse-width modulated signal having a duty cycle DC_{TRGT} representative of the target current I_{TRGT} for the load current I_{LOAD}. In addition, the digital control circuit 252 may comprise a digital-to-analog converter (DAC) for generating the DC target-current control signal V_{TRGT-DC} that may be directly coupled to the non-inverting input of the operational amplifier U226 (e.g., without requiring the resistor R230 and the capacitor C232).

The control loop circuit 220 may comprise a capacitor C234 coupled between the inverting input and an output of the operational amplifier U226, such that the control loop circuit 220 may be configured to integrate the error between the peak-current feedback signal V_{FB-PK} and the DC target-current control signal V_{TRGT-DC}. The control loop circuit 220 may generate the drive signal V_{DR} that may be received by a gate of the regulation FET Q212 for controlling the regulation FET in the linear region to provide a controllable impedance in series with the LED light source 202 (e.g., the regulation FET may be operated as a linear regulator). The output of the operational amplifier U226 may be coupled to the gate of the regulation FET Q212 through another filter circuit (e.g., a low-pass RC filter circuit) including a resistor R236 (e.g., having a resistance of approximately 1 kΩ) and a capacitor C238 (e.g., having a capacitance of approximately 0.1 μF).

The digital control circuit 252 may control the dimming control signal V_{DIM} to render the dimming FET Q216 conductive and non-conductive to adjust average magnitude of the load current I_{LOAD}. For example, the digital control circuit 252 may be configured to pulse-width modulate (PWM) the load current I_{LOAD} by generating the dimming control signal V_{DIM} as a pulse-width modulated (PWM) signal at a dimming frequency f_{DIM}. The digital control circuit 252 may be configured to adjust a duty cycle DC_{DIM} of the dimming control signal V_{DIM} to adjust the average magnitude of the load current I_{LOAD}. When the digital control circuit 252 is pulse-width modulating the dimming control signal V_{DIM}, the load current I_{LOAD} may be characterized by a load-current frequency f_{LOAD} that is approximately equal to the dimming frequency of the dimming control signal V_{DIM}. The load-current frequency f_{LOAD} may be high enough to prevent flickering in the LED light source 202 that may be visible to the human eye.

The digital control circuit 252 may be configured to render the controllable switch 222 conductive and non-conductive in coordination with the dimming control signal V_{DIM}. For example, the digital control circuit 252 may be configured to render the controllable switch 222 conductive at approximately the same time or slightly after the digital control circuit renders the dimming FET Q216 conductive. The digital control circuit 252 may be configured to render the controllable switch 222 non-conductive at approximately the same time or slightly before the digital control circuit renders the dimming FET Q216 non-conductive. This way, the magnitude of the peak-current feedback signal V_{FB-PK} may be representative of a peak magnitude I_{PK} of the load current I_{LOAD}, which may prevent erroneous operation of the control circuitry in various situations. For example, since the dimming FET Q216 may be coupled between the current feedback resistor R214 and circuit common, the magnitude of the current feedback signals V_{FB} may be pulled up towards the bus voltage V_{BUS} when the dimming FET Q216 is non-conductive. This may cause the control loop circuit 220 to incorrectly drive the regulation FETs Q212. By configuring the digital control circuit 252 to control when the controllable switch 222 is rendered conductive, erroneous generation of the drive signal V_{DR} may be avoided.

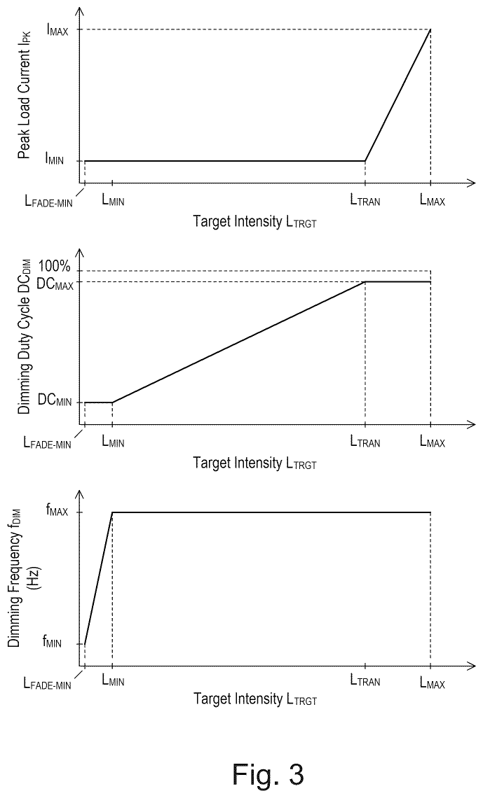

The digital control circuit 252 may control the duty cycle DC_{TRGT} of the PWM target-current control signal V_{TRGT-PWM}, the duty cycle DC_{DIM} of the dimming control signal V_{DIM}, and/or the dimming frequency f_{DIM} of the dimming control signal V_{DIM} as a function of the target intensity L_{TRGT}. FIG. 3 shows example plots of the relationship between the peak current I_{PK} of the load current I_{LOAD} and the target intensity L_{TRGT}, the relationship between the duty cycle DC_{DIM} of the dimming control signal V_{DIM} and the target intensity L_{TRGT}, and the relationship between the dimming frequency f_{DIM} of the dimming control signal V_{DIM} and the target intensity L_{TRGT}.

When the target intensity L_{TRGT} of the LED light source 202 is greater than or equal to a transition intensity L_{TRAN}, the digital control circuit 252 may be configured to render the dimming FET Q216 conductive (e.g., conductive at approximately all times) and adjust the peak magnitude I_{PK} of the load current I_{LOAD} to adjust the intensity of the LED light source (e.g., using a constant current reduction (CCR) dimming technique). For example, the digital control circuit 252 may adjust the duty cycle DC_{TRGT} of the PWM target-current control signal V_{TRGT-PWM} to cause the control loop circuit 220 to adjust the peak magnitude I_{PK} of the load current I_{LOAD} towards the target current I_{TRGT}, which may range between a maximum current IMAX and a minimum current IMIN. When the target intensity L_{TRGT} of the LED light source 202 is greater than or equal to the transition intensity L_{TRAN}, the duty cycle DC_{DIM} of the dimming control signal V_{DIM} may be held constant at a maximum duty cycle DC_{MAX}. The maximum duty cycle DC_{MAX} may be less than 100% (e.g., as shown in FIG. 3), such that the digital control circuit 252 may pulse-width modulate the load current I_{LOAD}. The maximum duty cycle DC_{MAX} may be equal to 100%, such that the dimming FET Q216 may be conductive at all times when the target intensity L_{TRGT} of the LED light source 202 is greater than or equal to the transition intensity L_{TRAN}.

When the target intensity L_{TRGT} of the LED light source 202 is less than the transition intensity L_{TRAN}, the digital control circuit 252 may be configured to control the dimming FET Q216 to adjust the intensity of the LED light source (e.g., using a pulse-width modulation (PWM) dimming technique). When using the PWM dimming technique, the digital control circuit 252 may be configured to maintain the duty cycle DC_{TRGT} of the target-current control signal V_{TRGT-PWM} constant to maintain the target current I_{TRGT} constant, and adjust the duty cycle DC_{DIM} of the dimming control signal V_{DIM} to adjust the magnitude of the load current I_{LOAD}. For example, the digital control circuit 252 may adjust the duty cycle DC_{DIM} as a function of the target intensity L_{TRGT} (e.g., linearly) as shown in FIG. 3. The control loop circuit 220 may continue to regulate the peak magnitude I_{PK} of the load current I_{LOAD} towards the target current I_{TRGT} when the dimming FET Q216 is conductive. The control loop circuit 220 may be characterized by a time constant that is much greater than the load-current period T_{LOAD} of the load current I_{LOAD}, for example, to help avoid changes in the magnitude of the drive signal V_{DR} when the dimming FET Q216 is non-conductive.

The digital control circuit 252 may be configured to fade (e.g., gradually adjust over a period of time) the target intensity L_{TRGT} (and thus the present intensity) of the LED light source 202. The digital control circuit 252 may be configured to fade the LED light source 202 from off to on by slowly increasing the present intensity L_{PRES} of the LED light source from a minimum fading intensity L_{FADE-MIN}, which may be less than the minimum intensity L_{MIN} (e.g., such as approximately 0.02%), to the target intensity L_{TRGT}. The digital control circuit 252 may be configured to fade the LED light source 202 from on to off by slowly decreasing the present intensity L_{PRES} of the LED light source from an initial intensity greater than or equal to the minimum intensity L_{MIN} to the minimum fading intensity L_{FADE-MIN} at which point the digital control circuit 252 may turn off the LED light source. As shown in FIG. 3, when the target intensity L_{TRGT} is less than the minimum intensity L_{MIN}, the digital control circuit 252 may adjust the dimming frequency f_{DIM} of the dimming control signal V_{DIM} with respect to the target current I_{TRGT} (e.g., while holding the duty cycle DC_{TRGT} of the target-current control signal V_{TRGT-PWM} and the duty cycle DC_{DIM} of the dimming control signal V_{DIM} constant).

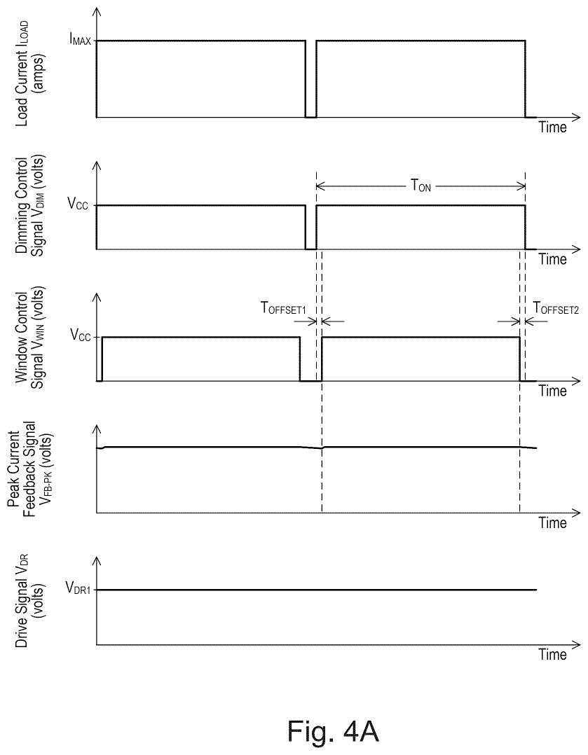

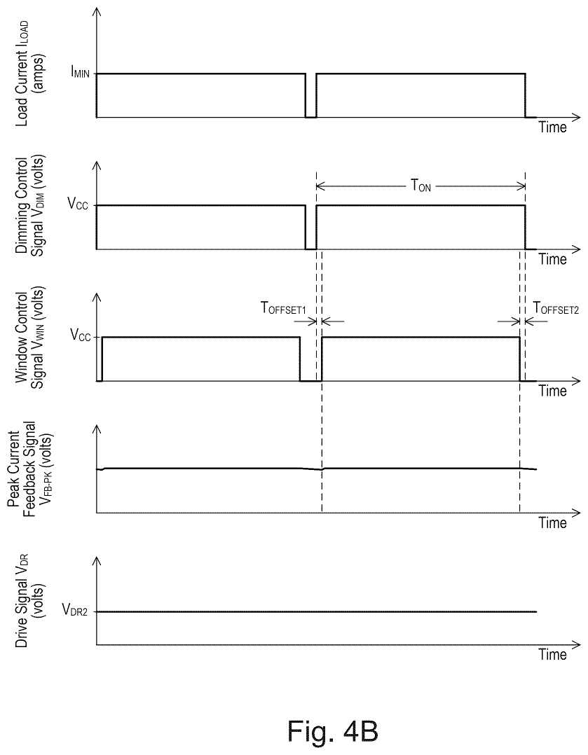

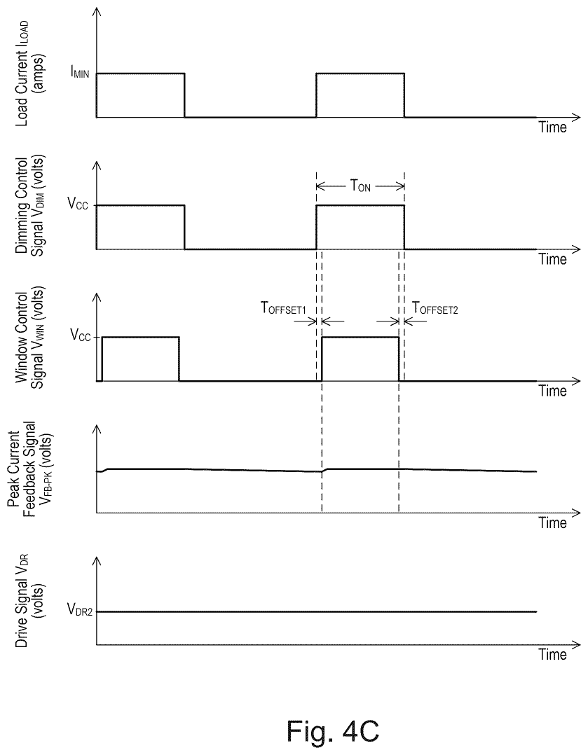

FIGS. 4A-4C show waveforms that illustrate the operation of the LED drive circuit 210 and the control loop circuit 220 of FIG. 2. In the example shown in FIG. 4A, the target intensity L_{TRGT} may be equal to and/or close to the maximum intensity L_{MAX}. The peak current I_{PK} of the load current I_{LOAD} may be controlled to the maximum current IMAX. The duty cycle DC_{DIM} of the dimming control signal V_{DIM} may be controlled to the maximum duty cycle DC_{MAX} (e.g., at 99%) resulting in prolonged on time T_{ON} of the dimming control signal. The digital control signal 252 may drive the window control signal V_{WIN} high towards the supply voltage V_{CC} after a first offset time period T_{OFFSET1} from when the dimming control signal V_{DIM} is driven high. The digital control signal 252 may drive the window control signal V_{WIN} low towards circuit common at a time that is a second offset time period T_{OFFSET2} before when the dimming control signal V_{DIM} is driven low. The peak current feedback signal V_{FB-PK} may have a magnitude that is dependent upon (e.g., representative of) the peak magnitude I_{PK} of the load current I_{LOAD} (e.g., the maximum current IMAX). The drive signal V_{DR} provided to the gate of the regulation transistor Q212 may be at a first magnitude V_{DR1}.

In the example shown in FIG. 4B, the target intensity L_{TRGT} may be equal to approximately the transition intensity L_{TRAN}. The peak current I_{PK} of the load current I_{LOAD} may be controlled to approximately the minimum current IMIN. The duty cycle DC_{DIM} of the dimming control signal V_{DIM} may still be controlled to the maximum duty cycle DC_{MAX} resulting in a similar on time T_{ON} of the dimming control signal as shown in FIG. 4A. The digital control signal 252 may drive the window control signal V_{WIN} high towards the supply voltage V_{CC} after a first offset time period T_{OFFSET1} from when the dimming control signal V_{DIM} is driven high. The digital control signal 252 may drive the window control signal V_{WIN} low towards circuit common at a time that is a second offset time period T_{OFFSET2} before when the dimming control signal V_{DIM} is driven low. The peak current feedback signal V_{FB-PK} may have a magnitude that is dependent upon (e.g., representative of) the peak magnitude I_{PK} of the load current I_{LOAD} (e.g., the minimum current IMIN). The drive signal V_{DR} provided to the gate of the regulation transistor Q212 may be at a second magnitude V_{DR2}.

In the example shown in FIG. 4C, the target intensity L_{TRGT} may be less than the transition intensity L_{TRAN} and greater than the minimum intensity L_{MIN}. As in FIG. 4B, the peak current I_{PK} of the load current I_{LOAD} may be controlled to be approximately the minimum current IMIN. The duty cycle DC_{DIM} of the dimming control signal V_{DIM} may be controlled to be less than the maximum duty cycle DC_{MAX} resulting in smaller on time T_{ON} of the dimming control signal than shown in FIGS. 4A and 4B. The digital control signal 252 may drive the window control signal V_{WIN} high towards the supply voltage V_{CC} after a first offset time period T_{OFFSET1} from when the dimming control signal V_{DIM} is driven high. The digital control signal 252 may drive the window control signal V_{WIN} low towards circuit common at a time that is a second offset time period T_{OFFSET2} before when the dimming control signal V_{DIM} is driven low. The peak current feedback signal V_{FB-PK} may have a magnitude that is dependent upon the peak magnitude I_{PK} of the load current I_{LOAD} (e.g., the minimum current IMIN). The drive signal V_{DR} provided to the gate of the regulation transistor Q212 may be at approximately the second magnitude V_{DR2} (e.g., as in FIG. 4B).

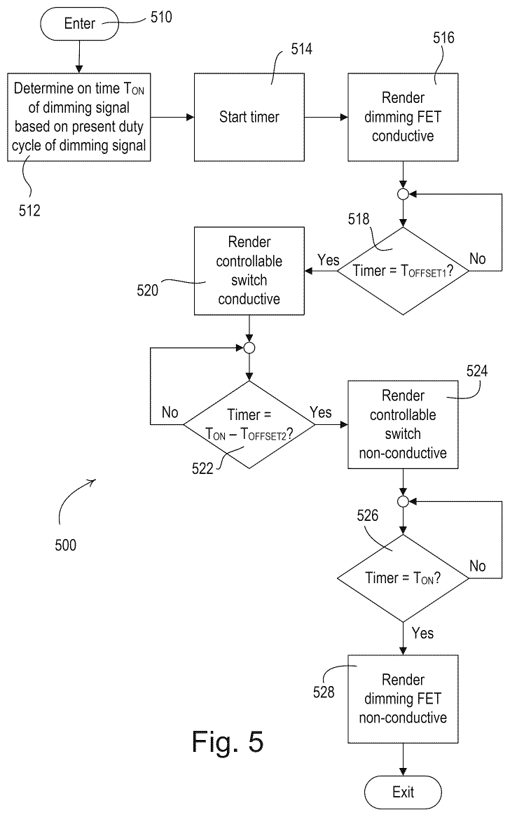

FIG. 5 is a simplified flow diagram of an example control procedure 500 for controlling a control loop circuit as described herein (e.g., the control loop circuit 220 of FIG. 2). The control procedure 500 may be executed by the digital control circuit 252 at step 510, for example, periodically and/or in response to a change of the target current I_{TRGT} for the light source 202. At 512, the digital control circuit may determine the on time T_{ON} of the dimming control signal V_{DIM}, for example, based on the present duty cycle of the dimming control signal. A timer may be started at 514 and the dimming FET Q216 may be rendered conductive at 516, for example by driving the dimming control signal V_{DIM} high (e.g., at approximately the same time that the timer is started). The value of the timer may be compared (e.g., periodically) to a first offset time period T_{OFFSET1} at 518. Once the timer value reaches the first offset time period T_{OFFSET1}, the digital control circuit 252 may render the controllable switch 222 conductive at 520, for example by driving the feedback window control signal V_{WIN} high. The digital control circuit 252 may then continue to check (e.g., periodically) the value of the timer at 522 against a value that is equal to the difference between the on time T_{ON} and a second offset time period T_{OFFSET2} (e.g., T_{ON}-T_{OFFSET2}). Once the timer value reaches the difference between the on time T_{ON} and a second offset time period T_{OFFSET2}, the digital control circuit 252 may render the controllable switch 222 non-conductive at 524, for example by driving feedback window control signal V_{WIN} low. Subsequently, the digital control circuit 252 may continue to monitor the value of the timer at 526 until that value reaches the on time T_{ON}. At that point, the digital control circuit 252 may render the dimming FET Q216 non-conductive at 528, for example by driving the dimming control signal V_{DIM} high, and the control procedure 500 may exit.

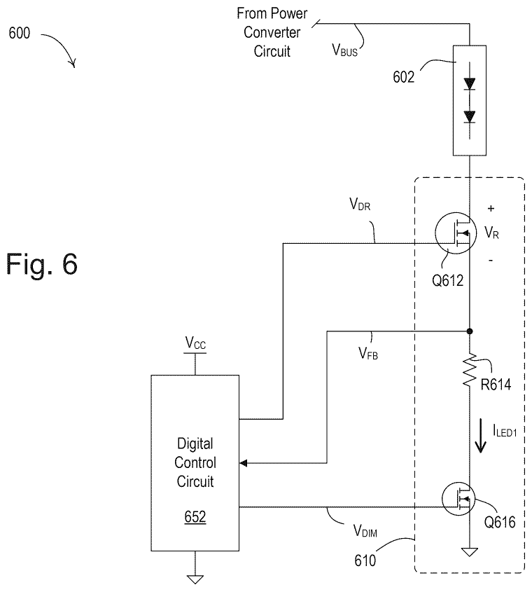

Part or the entirety of the functionality of the control loop circuit 220 may be implemented in a digital control circuit (e.g., the digital control circuit 252 or another digital control circuit of the control device 200). FIG. 6 is a simplified schematic diagram of a circuit 600 that may be used to realize the functionality of the LED drive circuit 210 and/or the control loop circuit 220 shown in FIG. 2. The circuit 600 may comprise an LED drive circuit 610, which may be implemented and configured in a similar manner as the LED drive circuit 210. For example, the LED drive circuit 610 may comprise a regulation device such as a regulation FET Q612 (e.g., similar to the regulation FET Q212). The LED drive circuit 610 may comprise a current feedback circuit (e.g., a current feedback resistor 614, which may be similar to the current feedback resistor R214). The LED drive circuit 610 may further comprise a dimming device such as a dimming FET Q616 (e.g., similar to the dimming FET Q216) coupled between the current feedback resistor 614 and circuit common. The digital control circuit 652 may generate a dimming control signal V_{DIM} that may be received by a gate of the dimming FET Q616. The dimming FET Q616 may be rendered conductive and non-conductive in response to the dimming control signal V_{DIM} for adjusting an average magnitude of the load current I_{LOAD} conducted through an LED light source 602.

The digital control circuit 652 may sample a current feedback signal V_{FB} generated via the current feedback resistor 614 during a time window in order to derive an average of the feedback signal that may be representative of a peak magnitude I_{PK} of the load current I_{LOAD}. The digital control circuit 652 may control the time window in coordination with the dimming control signal V_{DIM}. For example, the digital control circuit 652 may control the time window to start at approximately the same time or slightly after (e.g., an offset time period after) the time when the digital control circuit renders the dimming FET Q616 conductive. The digital control circuit 652 may control the time window to end at approximately the same time or slightly before (e.g., an offset time period before) the time when the digital control circuit renders the dimming FET Q616 non-conductive. The derived feedback signal may be filtered (e.g., via a digital low pass filter) and used to generate a drive signal V_{DR} that may be received by a gate of the regulation FET Q612 for controlling the regulation FET in the linear region to provide a controllable impedance in series with the LED light source 602 (e.g., to operate the regulation FET as a linear regulator).

The digital control circuit 652 may control the dimming control signal V_{DIM} to render the dimming FET Q616 conductive and non-conductive to adjust an average magnitude of the load current I_{LOAD}. For example, the digital control circuit 652 may be configured to pulse-width modulate the load current I_{LOAD} by generating the dimming control signal V_{DIM} as a pulse-width modulated signal at a dimming frequency f_{DIM}. The digital control circuit 652 may be configured to adjust a duty cycle DC_{DIM} of the dimming control signal V_{DIM} to adjust the average magnitude of the load current I_{LOAD}. When the digital control circuit 652 is pulse-width modulating the dimming control signal V_{DIM}, the load current I_{LOAD} may be characterized by a load-current frequency f_{LOAD} that is approximately equal to the dimming frequency of the dimming control signal V_{DIM}. The load-current frequency f_{LOAD} may be high enough to prevent flickering in the LED light source 602 that may be visible to the human eye. The digital control circuit 652 may be configured to maintain the magnitude of the drive signal V_{DR} when the dimming FETs Q616 is non-conductive.

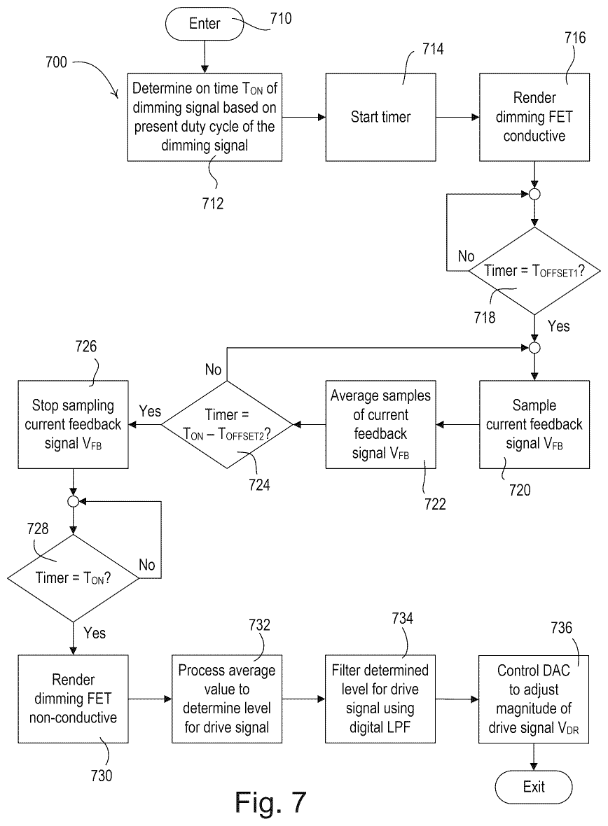

FIG. 7 is a simplified flow diagram of an example control procedure 700 for controlling the circuit 600 shown in FIG. 6. The control procedure 700 may be executed by the digital control circuit 652 at step 710, for example, periodically and/or in response to a change of the target current I_{TRGT} for the light source 602. At 712, the digital control circuit 652 may determine the on time T_{ON} of the dimming control signal V_{DIM}, for example, based on the present duty cycle of the dimming control signal. A timer may be started at 714 when the dimming FET Q616 is rendered conductive at 716. The value of the timer may be compared (e.g., periodically compared) to a first offset time period T_{OFFSET1} at 718. Once the timer value reaches the first offset time period T_{OFFSET1} but is still less than the on time T_{ON} by at least a second offset time period T_{OFFSET2} (e.g., Timer<T_{ON}-T_{OFFSET2}), the digital control circuit 652 may repetitively sample the current feedback signal V_{FB} at 720 and calculate an average of the samples at 722. At 724, the digital control circuit 652 may determine that the timer value has reached T_{ON}-T_{OFFSET2} and may subsequently stop sampling the current feedback signal V_{FB} at 726. The digital control circuit 652 may further determine, at 728, that the end of the on time T_{ON} has been reached, at which point the digital control circuit 652 may render the dimming FET 616 non-conductive at 730 and may process the average value of the current feedback signal V_{FB} to determine an appropriate level for the drive signal V_{DR} at 732. The determined level for the drive signal V_{DR} may be filtered (e.g., using a digital low pass filter (LPF)) at 734. Based on the filtered level, the digital control circuit 562 may generate a DC voltage at 736 (e.g., using a DAC or by generating a PWM signal that may be filtered with an external RC filter) for driving the regulation FET 612. The control procedure 700 may then exit.

Although described with reference to a controllable light source and/or an LED driver, one or more embodiments described herein may be used with other load control devices. For example, one or more of the embodiments described herein may be performed by a variety of load control devices that are configured to control of a variety of electrical load types, such as, for example, a LED driver for driving an LED light source (e.g., an LED light engine); a screw-in luminaire including a dimmer circuit and an incandescent or halogen lamp; a screw-in luminaire including a ballast and a compact fluorescent lamp; a screw-in luminaire including an LED driver and an LED light source; a dimming circuit for controlling the intensity of an incandescent lamp, a halogen lamp, an electronic low-voltage lighting load, a magnetic low-voltage lighting load, or another type of lighting load; an electronic switch, controllable circuit breaker, or other switching device for turning electrical loads or appliances on and off; a plug-in load control device, controllable electrical receptacle, or controllable power strip for controlling one or more plug-in electrical loads (e.g., coffee pots, space heaters, other home appliances, and the like); a motor control unit for controlling a motor load (e.g., a ceiling fan or an exhaust fan); a drive unit for controlling a motorized window treatment or a projection screen; motorized interior or exterior shutters; a thermostat for a heating and/or cooling system; a temperature control device for controlling a heating, ventilation, and air conditioning (HVAC) system; an air conditioner; a compressor; an electric baseboard heater controller; a controllable damper; a humidity control unit; a dehumidifier; a water heater; a pool pump; a refrigerator; a freezer; a television or computer monitor; a power supply; an audio system or amplifier; a generator; an electric charger, such as an electric vehicle charger; and an alternative energy controller (e.g., a solar, wind, or thermal energy controller). A single control circuit may be coupled to and/or adapted to control multiple types of electrical loads in a load control system.

1. A light-emitting diode (LED) lighting controller couplable to one or more LED sources, comprising:
control circuitry to:
receive, via communication interface circuitry, one or more inputs that include data indicative of a target intensity of the one or more LED sources;
determine respective target load current for each of the one or more LED sources using the received target intensity;
determine, one or more parameters of a pulse width modulated (PWM) control signal for each respective one of the one or more LED sources based on the received target intensity, the one or more PWM control signal parameters including at least one of:
a pulse width modulated (PWM) frequency of the PWM control signal; or
a PWM pulse duration of the PWM control signal;
communicate the respective PWM control signal to each of one or more controllably conductive devices, each of the one or more controllably conductive devices coupled in electrical series between respective ones of the one or more LED sources and a circuit common;
communicate the determined respective target load current to each of one or more load current control circuits, each of the one or more load current control circuits coupled in electrical series with respective ones of the one or more LED sources; and
communicate a respective load current sampling window signal to each of the one or more load current control circuits, the load current sampling window synchronized with PWM control signal.

2. The LED lighting controller of claim 1, wherein to communicate the respective load current sampling window signal to each of the one or more load current control circuits, the control circuitry to further:
communicate a respective load current sampling window signal to each of the one or more load current control circuits, the load current sampling window to begin after expiration of an offset time from the start of a PWM pulse and end synchronously with the end of the PWM pulse.

3. The LED lighting controller of claim 2, wherein the control circuitry to further:
receive, via communication interface circuitry, one or more signals that include data indicative of a target color temperature of the one or more LED sources;
determine a respective updated target load current for each of the one or more LED sources using the received target intensity and the received target color temperature;
determine one or more updated parameters of a pulse width modulated (PWM) control signal for each respective one of the one or more LED sources using the received target intensity and the received target color temperature, the one or more updated PWM control signal parameters including at least one of:
an updated pulse width modulated (PWM) frequency of the PWM control signal; or
an updated PWM pulse duration of the PWM control signal;
communicate the respective updated PWM control signal to each of the one or more controllably conductive devices;
communicate the respective updated target load current to each of one or more load current control circuits; and
communicate the respective load current sampling window signal to each of the one or more load current control circuits, the load current sampling window synchronized with PWM control signal.

4. The LED lighting controller of claim 1 wherein to receive the one or more signals that include the data indicative of the target intensity of the one or more LED sources, the control circuitry to further:
receive, via communicatively coupled wireless communication interface circuitry, the one or more signals that include the data indicative of the target intensity of the one or more LED sources.

5. The LED lighting controller of claim 1 wherein to communicate the respective PWM control signal to each of the one or more controllably conductive devices, the control circuitry to further:
communicate the respective PWM control signal as a gate voltage signal to each of one or more field effect transistors (FETs).

6. The LED lighting controller of claim 1 wherein to determine the respective the target load current for each of the one or more LED sources using the received target intensity, the control circuitry to further:
retrieve data representative of the respective target load current for each of the one or more LED sources from communicatively coupled memory circuitry.

7. A light-emitting diode (LED) control method, comprising:
receiving, by LED control circuitry via communication interface circuitry, one or more inputs that include data indicative of a target intensity of the one or more LED sources;
determining by the LED control circuitry, a respective target load current for each of the one or more LED sources using the received target intensity;
determining by the LED control circuitry, one or more parameters of a pulse width modulated (PWM) control signal for each respective one of the one or more LED sources based on the received target intensity, the one or more PWM control signal parameters including at least one of:
a pulse width modulated (PWM) frequency of the PWM control signal; or
a PWM pulse duration of the PWM control signal;
communicating by the LED control circuitry, the respective PWM control signal to each of one or more controllably conductive devices, each of the one or more controllably conductive devices coupled in electrical series between respective ones of the one or more LED sources and a circuit common;
communicating by the LED control circuitry, the determined respective target load current to each of one or more load current control circuits, each of the one or more load current control circuits coupled in electrical series between respective ones of the one or more LED sources and the circuit common; and
communicating by the LED control circuitry, a respective load current sampling window signal to each of the one or more load current control circuits, the load current sampling window synchronized with PWM control signal.

8. The LED control method of claim 7, wherein communicating the respective load current sampling window signal to each of the one or more load current control circuits, further comprises:
communicating by the LED control circuitry, a respective load current sampling window signal to each of the one or more load current control circuits, the load current sampling window to begin after expiration of an offset time from the start of a PWM pulse and end synchronously with the end of the PWM pulse.

9. The LED control method of claim 8, further comprising:
receiving by LED control circuitry via communication interface circuitry, one or more signals that include data indicative of a target color temperature of the one or more LED sources;
determining by the LED control circuitry, a respective updated target load current for each of the one or more LED sources using the received target intensity and the received target color temperature;
determining by the LED control circuitry, one or more updated parameters of a pulse width modulated (PWM) control signal for each respective one of the one or more LED sources using the received target intensity and the received target color temperature, the one or more updated PWM control signal parameters including at least one of:
an updated pulse width modulated (PWM) frequency of the PWM control signal; or
an updated PWM pulse duration of the PWM control signal;
communicating by the LED control circuitry, the respective updated PWM control signal to each of the one or more controllably conductive devices;
communicating by the LED control circuitry, the respective updated target load current to each of one or more load current control circuits; and
communicating by the LED control circuitry, the respective load current sampling window signal to each of the one or more load current control circuits, the load current sampling window synchronized with PWM control signal.

10. The LED control method of claim 7 wherein receiving the one or more signals that include the data indicative of the target intensity of the one or more LED sources, further comprising:
receiving by the LED control circuitry via wireless communication interface circuitry, the one or more signals that include data indicative of the target intensity of the one or more LED sources.

11. The LED control method of claim 7 wherein communicating the respective PWM control signal to each of the one or more controllably conductive devices, further comprising:
communicating by the LED control circuitry, the respective PWM control signal as a gate voltage to each of one or more field effect transistors (FETs).

12. The LED control method of claim 7 wherein determining the respective the target load current for each of the one or more LED sources using the received target intensity, further comprising:
retrieving by the LED control circuitry, data representative of the respective target load current for each of the one or more LED sources from communicatively coupled memory circuitry.

13. A non-transitory, machine-readable, storage device that includes instructions that, when executed by light-emitting diode (LED) control circuitry, causes the LED control circuitry to:
receive, via communication interface circuitry, one or more inputs that include data indicative of a target intensity of the one or more LED sources;
determine respective target load current for each of the one or more LED sources using the received target intensity;
determine, one or more parameters of a pulse width modulated (PWM) control signal for each respective one of the one or more LED sources based on the received target intensity, the one or more PWM control signal parameters including at least one of:
a pulse width modulated (PWM) frequency of the PWM control signal; or
a PWM pulse duration of the PWM control signal;
communicate the respective PWM control signal to each of one or more controllably conductive devices, each of the one or more controllably conductive devices coupled in electrical series between respective ones of the one or more LED sources and a circuit common;
communicate the determined respective target load current to each of one or more load current control circuits, each of the one or more load current control circuits coupled in electrical series with respective ones of the one or more LED sources; and
communicate a respective load current sampling window signal to each of the one or more load current control circuits, the load current sampling window synchronized with PWM control signal.

14. The non-transitory, machine-readable, storage device of claim 13, wherein the instructions that cause the LED control circuitry to communicate the respective load current sampling window signal to each of the one or more load current control circuits, further cause the LED control circuitry to:
communicate the respective load current sampling window signal to each of the one or more load current control circuits, the load current sampling window to begin after expiration of an offset time from the start of a PWM pulse and end synchronously with the end of the PWM pulse.

15. The non-transitory, machine-readable, storage device of claim 14 wherein the instructions, when executed by the LED control circuitry, further cause the LED control circuitry to:
receive, via communication interface circuitry, one or more signals that include data indicative of a target color temperature of the one or more LED sources;
determine a respective updated target load current for each of the one or more LED sources using the received target intensity and the received target color temperature;
determine one or more updated parameters of a pulse width modulated (PWM) control signal for each respective one of the one or more LED sources using the received target intensity and the received target color temperature, the one or more updated PWM control signal parameters including at least one of:
an updated pulse width modulated (PWM) frequency of the PWM control signal; or
an updated PWM pulse duration of the PWM control signal;
communicate the respective updated PWM control signal to each of the one or more controllably conductive devices;
communicate the respective updated target load current to each of one or more load current control circuits; and
communicate the respective load current sampling window signal to each of the one or more load current control circuits, the load current sampling window synchronized with PWM control signal.

16. The non-transitory, machine-readable, storage device of claim 13 wherein the instructions that cause the LED control circuitry to receive the one or more signals that include data indicative of a target intensity of the one or more LED sources, further cause the LED control circuitry to:
receive, via communicatively coupled wireless communication interface circuitry, the one or more signals that include the data indicative of the target intensity of the one or more LED sources.

17. The non-transitory, machine-readable, storage device of claim 13 wherein the instructions that cause the LED control circuitry to communicate the respective PWM control signal to each of the one or more controllably conductive devices, further cause the LED control circuitry to:
communicate the respective PWM control signal as a gate voltage to each of one or more field effect transistors (FETs).

18. The non-transitory, machine-readable, storage device of claim 13 wherein the instructions that cause the LED control circuitry to determine the respective the target load current for each of the one or more LED sources using the received target intensity, further cause the LED control circuitry to:
retrieve data representative of the respective target load current for each of the one or more LED sources from communicatively coupled memory circuitry.
